(19) United States
(12) Patent Application Publication
(10) Pub. No.: US 2013/0302535 A1
(43) Pub. Date: Nov. 14, 2013

(54) SPUTTER DEVICE AND METHOD FOR DEPOSITING THIN FILM USING THE SAME

(71) Applicants: Yun-Mo CHUNG, Yongin-City (KR); Jeong-Yeong JEONG, Yongin-City (KR); Jong-Ryuk PARK, Yongin-City (KR); Jin-Wook SEO, Yongin-City (KR)

(72) Inventors: Yun-Mo CHUNG, Yongin-City (KR); Jeong-Yeong JEONG, Yongin-City (KR); Jong-Ryuk PARK, Yongin-City (KR); Jin-Wook SEO, Yongin-City (KR)

(21) Appl. No.: 13/687,183

(22) Filed: Nov. 28, 2012

(30) Foreign Application Priority Data
May 10, 2012 (KR) 10-2012-0049894

(51) Int. Cl. C23C 14/34

(52) U.S. Cl. CPC C23C 14/34
USPC 427/569; 118/723 E

(57) ABSTRACT

A sputter device includes a cathode portion including a target support portion coupled to a front surface of a cathode main body, a target being mounted on the front surface of the cathode main body and being supported by the target support portion, an anode portion including an anode coupled to an anode main body, the anode main body surrounding a side and a bottom of the cathode portion, and the anode covering the target support portion and an edge of the target, an internal insulator between the cathode portion and the anode main body, an electrode insulator between the anode and each of the target support portion and the edge of the target, and a power source portion connected to the cathode portion and the anode portion.

### CROSS-REFERENCE TO RELATED APPLICATION

This application claims priority under 35 USC §119 to and the benefit of Korean Patent Application No. 10-2012-0049894 filed in the Korean Intellectual Property Office on May 10, 2012, the entire contents of which are incorporated herein by reference.

### BACKGROUND

1. Field

An exemplary embodiment relates to a sputter device and a thin film deposition method using the same. More particularly, an exemplary embodiment relates to a sputter device with a diode sputter deposition source that does not use a magnet, and to a thin film deposition method using the same.

2. Description of the Related Art

A deposition source of a conventional sputter device controls a magnetic field by disposing a magnetic substance in a lower portion of a target. The magnetic substance increases density of charges in a location close to the target surface to increase deposition efficiency, and improves quality by increasing energy of particles deposited to the target. However, a method using the conventional sputter device is not appropriate to be used in double-layered deposition, single-layered deposition, or doping of a material with a deposition rate of less than 1 Å/sec.

The above information disclosed in this Background section is only for enhancement of understanding of the background of the invention and therefore it may contain information that does not form the prior art that is already known in this country to a person of ordinary skill in the art.

### SUMMARY

Example embodiments have been made in an effort to provide a sputter device that can effectively form a good quality thin film.

According to an exemplary embodiment, a sputter device may include a cathode portion including a target support portion coupled to a front surface of a cathode main body, a target being mounted on the front surface of the cathode main body and being supported by the target support portion, an anode portion including an anode coupled to an anode main body, the anode main body surrounding a side and a bottom of the cathode portion, and the anode covering the target support portion and an edge of the target, an internal insulator between the cathode portion and the anode main body, an electrode insulator between the anode and each of the target support portion and the edge of the target, and a power source portion connected to the cathode portion and the anode portion.

An end portion of the electrode insulator may protrude further toward a center of the target than an end portion of the anode.

A protruded length of the electrode insulator may be about 1 mm to about 3 mm.

The protruded end portion of the electrode insulator may include an electric connection prevention groove extending toward a center of the target.

The protruded end portion of the electrode insulator may have an approximate shape of “C”.

The electrode insulator may have a thickness of about 1 mm to about 5 mm.

The anode may include an electrode extension portion bent away from the target.

The electrode insulator may completely separate the target from the anode.

The node may overlap only a first part of an upper surface of the electrode insulator, a second part of the upper surface of the electrode insulator being different than the first part and being exposed.

A length of electrode insulator may be longer than a length of the anode as measured from a same reference point on the anode main body.

According to another exemplary embodiment, a thin film deposition method may include mounting a target on the cathode portion, such that the target is on a front surface of a cathode main body of the cathode portion, and the target is supported by a target support portion coupled to the front surface of the cathode main body, arranging the anode portion on the cathode portion, such that the anode main body surrounds a side and a bottom of the cathode portion, an anode of the anode portion covers the target support portion and an edge of the target, and an electrode insulator is positioned between the anode and each of the target support portion and the edge of the target, and depositing deposition material to an exposed center portion of the target by applying a voltage to the cathode portion and the anode portion through a power source portion.

Depositing the deposition material may include depositing material in a plasma state.

### BRIEF DESCRIPTION OF THE DRAWINGS

FIG. 1 is a cross-sectional view of a sputter device according to a first exemplary embodiment.

FIG. 2 is a cross-sectional view of a sputter device according to a second exemplary embodiment.

FIG. 3 is an enlarged cross-sectional view of an electrode insulator of FIG. 2.

FIG. 4 is a cross-sectional view of a sputter device according to a third exemplary embodiment.

### DETAILED DESCRIPTION OF THE EMBODIMENTS

In the following detailed description, certain exemplary embodiments have been shown and described by way of illustration. As those skilled in the art would realize, the described embodiments may be modified in various different ways, all without departing from the spirit or scope of the inventive concept.

It shall be noted that the drawings are schematic and do not depict exact dimensions. The relative proportions and ratios of elements in the drawings may be exaggerated or diminished in size for the sake of clarity and convenience in the drawings, and such arbitrary proportions are only illustrative and not limiting in any way. Like reference numerals are used for like structures, elements, or parts shown in two or more drawings to show similar characteristics. When one part is said to be “over” or “on” another part, the one part may be directly over the other part or may be accompanied by another part interposed therebetween.

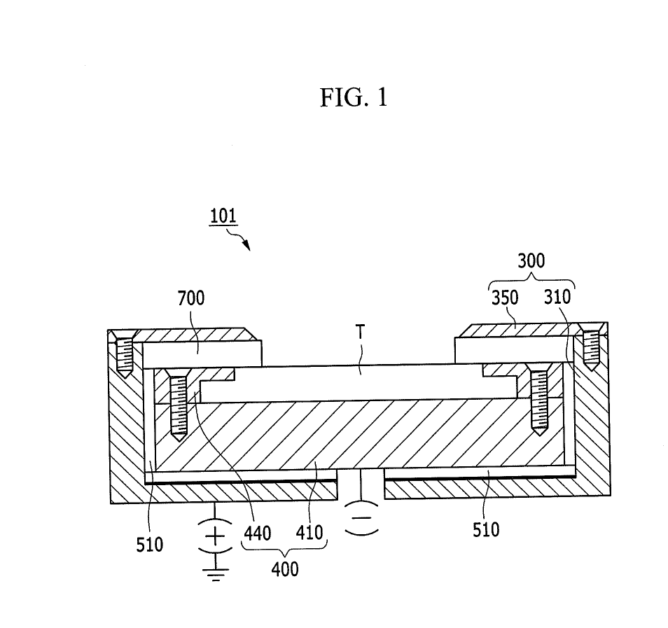

Hereinafter, a sputter device 101 according to a first exemplary embodiment will be described with reference to FIG. 1.

As shown in FIG. 1, the sputter device 101 according to the first exemplary embodiment includes a cathode portion 400, an anode portion 300, an internal insulator 510, an electrode insulator 700, and a power source unit.

The cathode portion 400 includes a cathode main body 410, e.g., a target T may be provided on a front surface of the cathode main body 410, and a target support portion 440 coupled to the front surface of the cathode main body 410 to support an edge of the target T. For example, the target support portion 440 is formed to have an inverted “L” shape cross-section, e.g., in a shape of “ [symbol] ,” to overlap portions of at least two different surfaces of the target T. For example, the target support portion 440 surrounds, e.g., surrounds an entire perimeter of, the edge of the target T. In addition, the target support portion 440 may be detachably coupled with the cathode main body 410 using a bolt. In addition, the target T provided on the cathode main body 410 is operated as a cathode in the cathode portion 400.

The anode portion 300 includes an anode main body 310 and an anode 350. The anode main body 310 surrounds a side and a bottom of the cathode portion 400, e.g., surrounds the side of the cathode portion 400 along an entire perimeter and the entire bottom of the cathode portion 400. The anode 350 covers the target support portion 440 and a part of the edge of the target T in a separated state, e.g., the anode 350 overlaps the entire top surface of the target support portion 440 and a part of the edge of the target T without being connected to either the target support portion 440 or the target T. Therefore, the anode 350 shields the edge of the target T and the target support portion 440, e.g., the edge along an entire perimeter of the target T, such that a center portion of the target T is exposed. As such, a deposition material is deposited in the exposed center portion of the target T, such that a thin film is formed. In addition, the anode 350 is coupled with the anode main body 310, e.g., the anode 350 may be detachably coupled with the anode main body 310 using a bolt.

The internal insulator 510 is provided between the anode main body 310 and the cathode portion 400 to insulate therebetween. The internal insulator 510 may be formed of various materials e.g., the internal insulator 510 may be formed of teflon.

The power source portion is connected with the cathode portion 400 and the anode portion 300 and applies a voltage thereto. In FIG. 1, (+) and (−) indicate the connection of the power source portion to the cathode and anode portions.

The electrode insulator 700 is disposed in a separate space between the anode 350 and the target support portion 440, and extends to overlap a part of the edge of the target T. In this case, an end portion of the electrode insulator 700 protrudes toward a center direction of the target T further than an end portion of the anode 350. In other words, the electrode insulator 700 extends beyond the anode 350, so a portion of an upper surface of the electrode insulator 700 is exposed. For example, a protruded length of the electrode insulator 700, i.e., a portion of the electrode insulator 700 extending beyond the anode 350, may be about 1 mm to about 3 mm. Since the electrode insulator 700 protrudes further than the anode 350, the anode 350 is completely separated from the target T by the electrode insulator 700 and may be stably prevented from being directly exposed to the target T.

In addition, the electrode insulator 700 may have a thickness of about 1 mm to about 5 mm. In this case, the thickness of the electrode insulator 700 may be adjusted within the given range in order to provide an optimum distance between the anode 350 and the target T for a plasma process. When the thickness of the electrode insulator 700 is smaller than 1 mm, insulation between the anode 350 and the target T cannot be stably assured. In addition, when the thickness of the electrode insulator 700 is greater than 5 mm, plasma may be unstably formed.

The electrode insulator 700 according to example embodiments is positioned in a space between the anode 350 and each of the target support portion 440 and the target T, so the electrode insulator 700 fills a gap between the anode 350 and each of the target T, which functions as a cathode, and the target support 440. As such, the electrode insulator 700 prevents arcing from occurring in the gap.

In contrast, if the electrode insulator 700 is not formed in the gap, the anode 350 may be exposed to each of the target T and the target support portion 440 through the gap. When the target T and the anode 350 are close each other, arcing may occur in the gap due to a voltage drop.

In addition, as the electrode insulator 700 is provided between the anode 350 and each of the target T and the target support portion 440 to fill the gap therebetween, an optimum distance between the anode 350 and the target T for the thin film process may be stably maintained without increasing a distance between the target T and the anode 350 and without arcing. In contrast, when a distance between the target T and the anode 350 is increased in order to remove arcing, plasma may become unstable so that a thin film may be unstably formed.

In addition, the electrode insulator 700 may prevent or substantially minimize particles from being generated due to deposition of a deposition material on an inner side of the anode 350. With such a configuration, the sputter device 101 according to the first exemplary embodiment may effectively form a thin film with improved quality. In particular, ultramicro deposition of less than 1×1014 atoms/cm² may be stably performed.

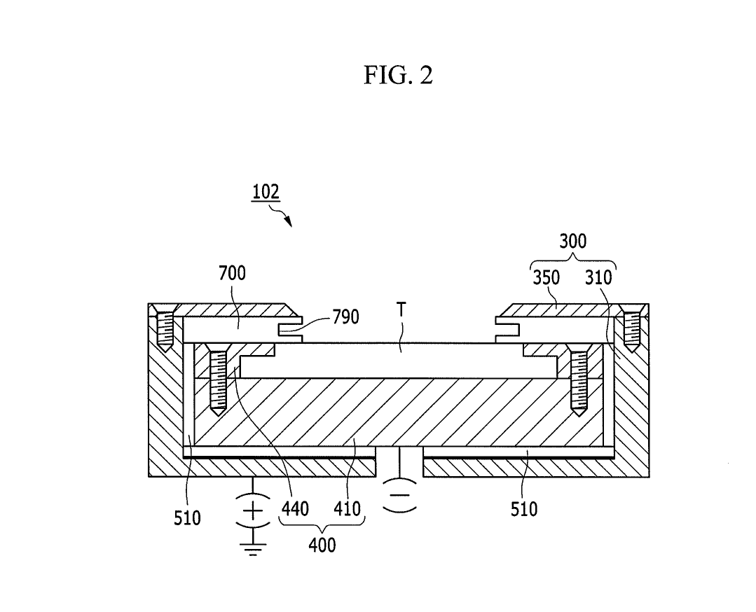

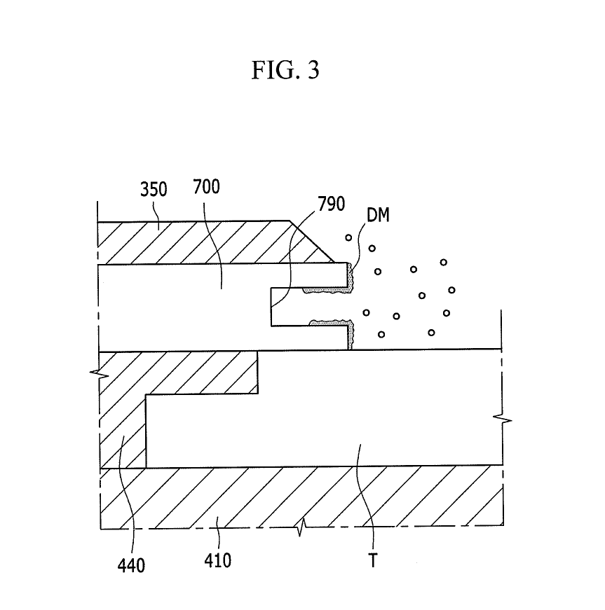

Hereinafter, a sputter device 102 according to a second exemplary embodiment will be described with reference to FIG. 2 and FIG. 3.

As shown in FIG. 2, the sputter device 102 according to the second exemplary embodiment is substantially the same as the sputter device 101, with the exception of including an electric connection prevention groove 790 at an end portion of the electrode insulator 700. In detail, the electric connection prevention groove 790 protrudes toward a center direction of the target T, as illustrated in FIG. 3, so an end portion of the electrode insulator 700 may be formed in the shape of “C”.

The electric connection prevention groove 790 formed in the protruded end of the electrode insulator 700 prevents the anode 350 and the target T from being electrically connected with each other due to a deposition material deposited to a side of the electrode insulator 700. In contrast, when the electric connection prevention groove 790 is not formed in the electrode insulator 700, i.e., when a vertical sidewall of the electrode insulator 700 is substantially flat, deposition material deposited on the vertical sidewall of the electrode insulator 700 may accumulate to extend from the anode 350 to the target T and may electrically connected therebetween.

However, according to the second exemplary embodiment, even if deposition material DM is deposited on the sidewall of the electrode insulator 700, electric connection between the anode 350 and the target T is short-circuited by the electric connection prevention groove 790, thereby effectively preventing the electric connection therebetween. With such a configuration, the sputter device 102 can further stably form a good quality thin film.

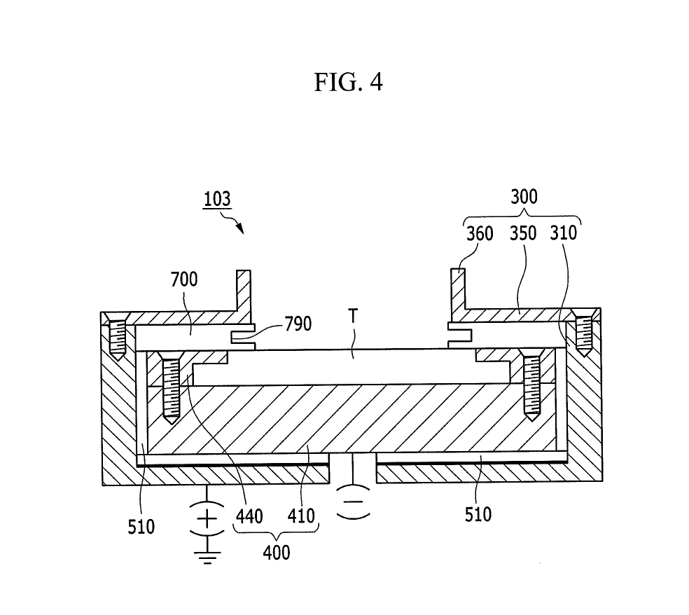

Hereinafter, a sputter device 103 according to a third exemplary embodiment will be described with reference to FIG. 4. The sputter device 103 may be substantially the same as the sputter device 101 or sputter device 102, with the exception of having an electrode extension portion 360 on the anode 350.

As shown in FIG. 4, the anode portion 300 of the sputter device 103 according to the third exemplary embodiment includes the electrode extension portion 360 bent and extended to an opposite direction of a direction of the target T from an end portion of the anode 350. For example, the electrode extension portion 360 may be bent perpendicularly with respect to the anode 350, and may extend away from the target T. The electrode extension portion 360 expands an area, e.g., increases an area of the end portion of the anode 350, to stably maintain plasma discharging.

In addition, the electric connection prevention groove 790 of the second exemplary embodiment may be selectively used in the third exemplary embodiment. With such a configuration, the sputter device 103 according to the third exemplary embodiment may further stably form a good quality thin film.

Meanwhile, a thin film deposition method using a sputter device according to the exemplary embodiments may include mounting a target on the front surface of the cathode main body 410, so the edge, e.g., only the edge, of the target may be supported by the target support portion 440. Next, a deposition material may be provided to the sputter device, so the deposition material may be deposited to an exposed center portion of the target by applying a voltage to the cathode portion 400 and the anode portion 300 through the power source portion. In this case, the deposition material may be in a plasma state.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

<Description of symbols>

| 101, 102, 103: sputter devices | 300: anode portion |
|---|---|
| 310: anode main body | 350: anode |
| 360: electrode extension portion | 400: cathode portion |
| 410: cathode main body | 440: target support portion |
| 510: internal insulator | 700: electrode insulator |
| 790: electric connection prevention groove | |
| T: target | DM: deposition material |

What is claimed is:

1. A sputter device, comprising:
a cathode portion including a target support portion coupled to a front surface of a cathode main body, a target being mounted on the front surface of the cathode main body and being supported by the target support portion;
an anode portion including an anode coupled to an anode main body, the anode main body surrounding a side and a bottom of the cathode portion, and the anode covering the target support portion and an edge of the target;
an internal insulator between the cathode portion and the anode main body;
an electrode insulator between the anode and each of the target support portion and the edge of the target; and
a power source portion connected to the cathode portion and the anode portion.

2. The sputter device of claim 1, wherein an end portion of the electrode insulator protrudes further toward a center of the target than an end portion of the anode.

3. The sputter device of claim 2, wherein a protruded length of the electrode insulator is about 1 mm to about 3 mm.

4. The sputter device of claim 2, wherein the protruded end portion of the electrode insulator includes an electric connection prevention groove extending toward a center of the target.

5. The sputter device of claim 4, wherein the protruded end portion of the electrode insulator has an approximate shape of “C”.

6. The sputter device of claim 1, wherein the electrode insulator has a thickness of about 1 mm to about 5 mm.

7. The sputter device of claim 1, wherein the anode includes an electrode extension portion bent away from the target.

8. The sputter device of claim 1, wherein the electrode insulator completely separates the target from the anode.

9. The sputter device of claim 1, wherein the anode overlaps only a first part of an upper surface of the electrode insulator, a second part of the upper surface of the electrode insulator being different than the first part and being exposed.

10. The sputter device of claim 1, wherein a length of electrode insulator is longer than a length of the anode as measured from a same reference point on the anode main body.

11. A thin film deposition method using a sputter device having an internal insulator between a cathode portion and an anode main body of an anode portion, the method comprising:
mounting a target on the cathode portion, such that the target is on a front surface of a cathode main body of the cathode portion, and the target is supported by a target support portion coupled to the front surface of the cathode main body;
arranging the anode portion on the cathode portion, such that the anode main body surrounds a side and a bottom of the cathode portion, an anode of the anode portion covers the target support portion and an edge of the target, and an electrode insulator is positioned between the anode and each of the target support portion and the edge of the target; and
depositing deposition material to an exposed center portion of the target by applying a voltage to the cathode portion and the anode portion through a power source portion.

12. The thin film deposition method of claim 11, wherein depositing the deposition material includes depositing material in a plasma state.
